(19) United States
(12) Patent Application Publication
(10) Pub. No.: US 2010/0021273 A1
(43) Pub. Date: Jan. 28, 2010

(54) CONCRETE VACUUM CHAMBER

(75) Inventors: ALEXANDER S. POLYAK, San Jose, CA (US); TOM K. CHO, Los Altos, CA (US); JOSEPH YUDOVSKY, Campbell, CA (US); ANTHONY VESCI, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/506,575

(22) Filed: Jul. 21, 2009

Related U.S. Application Data
(60) Provisional application No. 61/084,158, filed on Jul. 28, 2008.

(51) Int. Cl. H01L 21/677; B29C 45/14

(52) U.S. Cl. 414/217.1; 264/257

(57) ABSTRACT

The present invention embodies processing systems and vacuum chambers equipped to process substrates for flat panel displays, solar cells, or other electronic devices. The processing system and/or the vacuum chambers as well as their components and supporting structure are constructed of less costly materials and in a more energy efficient manner than that of current large area substrate processing systems. In one embodiment, the processing system chamber bodies and their supporting structures are constructed of reinforced concrete. In one embodiment, system processing chambers include a vacuum tight lining disposed inside reinforced concrete chamber bodies.

### CROSS-REFERENCE TO RELATED APPLICATIONS

This application claims benefit of U.S. provisional patent application Ser. No. 61/084,158, filed Jul. 28, 2008, which is herein incorporated by reference.

### BACKGROUND OF THE INVENTION

1. Field of the Invention

Embodiments of the present invention generally relate to equipment for processing large area substrates.

2. Description of the Related Art

As the size of substrates used to manufacture electronic devices, such as flat panel displays and solar panels, increases, the size of processing systems and vacuum chambers used therein for the fabrication of such devices must increase correspondingly. Presently, processing systems and their vacuum chambers must be equipped to process large area substrates up to 5.7 m²; however, the need to process increasingly larger substrates is inevitable.

In order to accommodate substrates of such size, current processing systems contain several tons of aluminum and stainless steel of which their chambers and supporting structures are fabricated. However, the difficulty, energy consumption, and cost of manufacturing and shipping processing systems of such size is a constant challenge that may ultimately limit both the processing system, vacuum chamber, and substrate size.

Therefore, a need exists for large area substrate processing systems and vacuum chambers that are less costly and more energy efficient to manufacture.

### SUMMARY OF THE INVENTION

In one embodiment of the present invention, a substrate processing system comprises a loadlock chamber having a chamber body and a substrate transfer port disposed therethrough, wherein the loadlock chamber body is comprised of reinforced concrete, a transfer chamber having a first wall with a substrate transfer port disposed therethrough and a second wall with a substrate transfer port disposed therethrough, and a vacuum processing chamber having a bottom, a sidewall, a showerhead, and a substrate support member forming a substrate processing region. In one embodiment, the loadlock chamber body is comprised of reinforced concrete. In one embodiment, the substrate transfer port in the first wall is in fluid communication with the substrate transfer port in the loadlock chamber body. In one embodiment, the first and second transfer chamber walls are comprised of reinforced concrete. In one embodiment, the sidewall has a substrate transfer port in fluid communication with the substrate transfer port of the second wall of the substrate transfer chamber. In one embodiment, the bottom, and sidewall are comprised of reinforced concrete.

In one embodiment of the present invention, a substrate processing system comprises a loadlock chamber having a chamber body and a substrate transfer port disposed therethrough, a transfer chamber having a wall and a substrate transfer port disposed therethrough, and a vacuum processing chamber having a bottom, a sidewall, a showerhead, and a substrate support member forming a substrate processing region, wherein the bottom, and sidewall are comprised of reinforced concrete. In one embodiment, the loadlock chamber body is comprised of reinforced concrete. In one embodiment, the transfer chamber wall is comprised of reinforced concrete.

In one embodiment, a vacuum processing chamber comprises a bottom wall, a sidewall, a showerhead, and a susceptor defining a processing volume, a reinforcing member disposed within the bottom wall, and aggregate filler disposed within the bottom wall.

In one embodiment, a vacuum chamber comprises a chamber body having walls defining a processing region therein, the chamber body having a substrate transfer port and a first vacuum port disposed therethrough, a vacuum pump in fluid connection with the processing region via the first vacuum port, a structural mesh disposed within the walls of the chamber body, and a filler material disposed within the walls of the chamber body.

In one embodiment, a method of constructing a vacuum processing chamber comprises forming a structural mesh in the shape of a chamber body having a bottom wall and a side wall, attaching a chamber liner having a bottom wall and a side wall to the structural mesh, distributing a filler material within and about the structural mesh, and curing the filler material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, top, plan view of a large area substrate processing system according to one embodiment of the present invention.

FIG. 2A is a schematic, cross-sectional view of one embodiment of a loadlock chamber according to the present invention.

FIG. 2B is a schematic, cross-sectional view of the loadlock chamber in FIG. 2A taken along section line B-B.

FIG. 3 is a schematic, cross-sectional view of one embodiment of a transfer chamber according to the present invention.

FIG. 4 is a schematic, cross-sectional view of one embodiment of a process chamber according to the present invention.

### DETAILED DESCRIPTION

The present invention embodies processing systems and vacuum chambers equipped to process substrates for flat panel displays, solar cells, or other electronic devices. The processing system and/or the vacuum chambers as well as their components and supporting structure are constructed of less costly materials and in a more energy efficient manner than that of current large area substrate processing systems. In one embodiment, the processing system chamber bodies and their supporting structures are constructed of reinforced concrete. In one embodiment, system processing chambers include a vacuum tight lining disposed inside reinforced concrete chamber bodies.

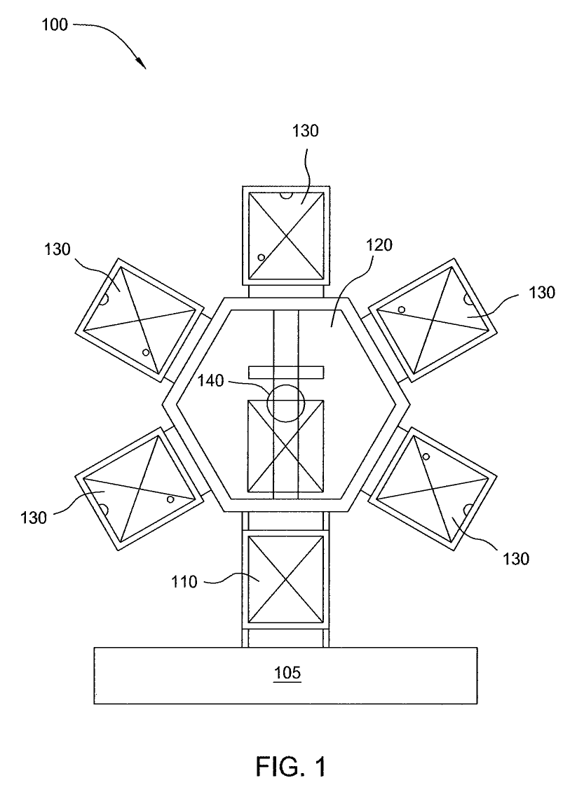

FIG. 1 is a schematic, top, plan view of a large area substrate processing system 100 according to one embodiment of the present invention. The processing system 100 may be used to perform one or more processing steps to form various regions of an electronic device on a large area substrate. The processing system 100 may include a plurality of process chambers 130, such as plasma enhanced chemical vapor deposition (PECVD) chambers, capable of depositing one or more desired layers on a substrate surface. In addition or alternative to PECVD chambers, the processing system 100 may include other process chambers 130 such as physical vapor deposition (PVD) chambers, chemical vapor deposition (CVD) chambers, ion metal implant (IMP) chambers, atomic layer deposition (ALD) chambers, thermal anneal chambers, or other chambers used in processing large areas substrates.

The processing system 100 includes a transfer chamber 120 coupled to at least one loadlock chamber 110 and the process chambers 130. The loadlock chamber 110 allows substrates to be transferred between the ambient environment of a factory interface 105 outside the processing system 100 and a vacuum environment within the transfer chamber 120 and process chambers 130. The loadlock chamber 110 may include one or more evacuatable regions for holding one or more substrates. The evacuatable regions are pumped down during input of substrates into the system 100 and are vented during output of the substrates from the processing system 100. The transfer chamber 120 includes at least one transfer robot 140 disposed therein adapted to transfer substrates between the loadlock chamber 110 and the process chambers 130. While five process chambers 130 are shown in FIG. 1, the processing system 100 may include any suitable number of process chambers 130, such as from one to seven or more process chambers 130.

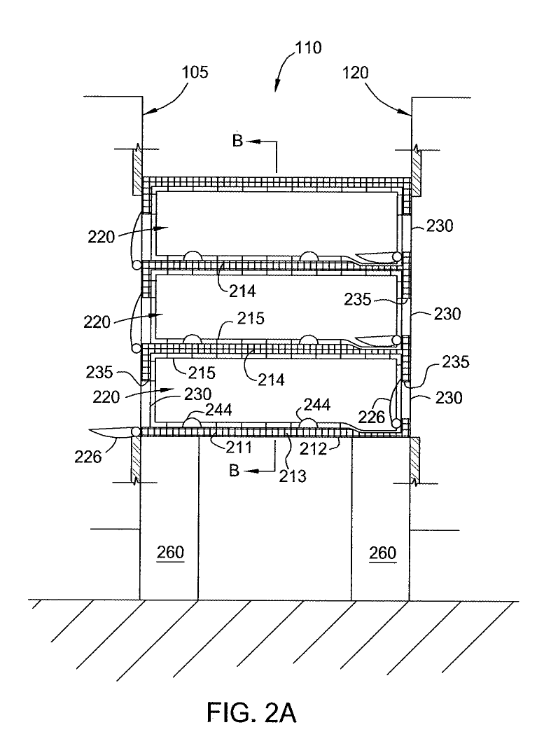

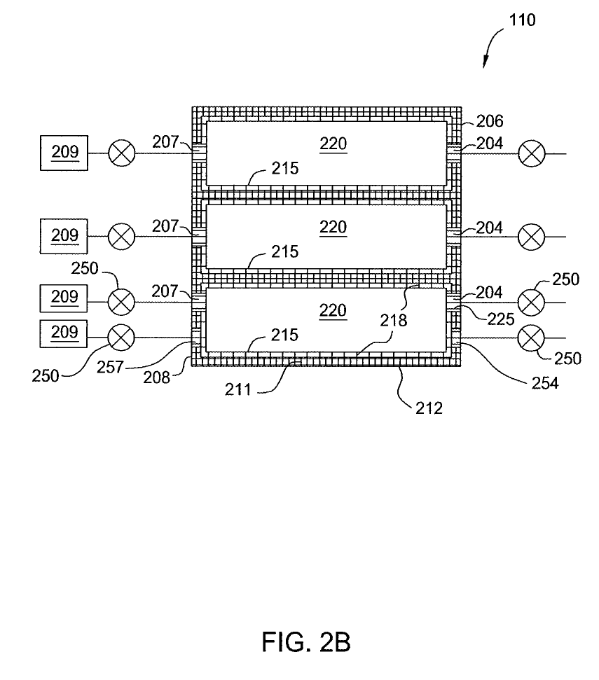

FIG. 2A is a schematic, cross-sectional view of one embodiment of a loadlock chamber 110. In one embodiment, loadlock chamber 110 includes a chamber body 212 with a plurality of vertically-stacked environmentally-isolated, single substrate sub-chambers 220 separated by a plurality of vacuum-tight horizontal interior walls 214. Two interior walls 214 are shown in FIG. 2. Although three single substrate sub-chambers 220 are shown in the embodiment depicted in FIG. 2, the chamber body 212 of the loadlock chamber 110 may include only one single substrate chamber. In other embodiments, the chamber body 212 may include N number of substrate sub-chambers 220 separated by N-1 number of horizontal interior walls 214, wherein N is a positive integer.

In one embodiment of the present invention, the chamber body 212 is constructed of reinforced concrete. The interior walls 214 may also be constructed of reinforced concrete. In one embodiment, the chamber body 212 and walls 214 include a reinforcing mesh 211 of wires or bars distributed with concrete filler 213 cured thereabout. The mesh 211 may be pre-tensioned to ensure the concrete filler 213 in the chamber body 212 and walls 214 remains in compression after being cured. The mesh 211 may be sized and distributed to withstand the pressures, such as vacuum pressures, encountered in normal operation of the loadlock chamber 110. In one embodiment, the interior surface of the chamber body 212 and walls 214 may be ground, polished, or otherwise treated, such as by applying permeating resins, to produce a vacuum tight finish.

In one embodiment, the reinforcing mesh 211 is comprised of a network of welded, carbon or stainless steel wires and/or bars. In one embodiment, a chamber liner 215 is disposed within and lining the chamber body 212 and interior walls 214. In one embodiment, the chamber liner 215 is a thin-walled structure formed in a vacuum tight manner. In one embodiment, the chamber liner 215 is constructed by bonding and/or welding sheets of carbon steel, stainless steel, or aluminum. In one embodiment, the chamber liner 215 is constructed by hydroforming aluminum tubing or sheet material.

In one embodiment, the concrete filler 213 is a cement, sand, and water mixture plastered within and about the reinforcing mesh 211 as known in the art of ferrocement ship hull construction. In one embodiment, the chamber liner 215 is attached to the reinforcing mesh 211, and the concrete filler 213 is applied between the chamber liner 215 and the reinforcing mesh 211 as well as within and about the reinforcing mesh 211.

In one embodiment, each of the sub-chambers 220 defined in the chamber body 212 includes two substrate access ports 230 coupled to the transfer chamber 120 or the factory interface 105. In the embodiment shown in FIG. 2, the access ports 230 are positioned on opposite sides of the chamber body 212. However, the access ports 230 may be positioned on adjacent sides of the chamber body 212. The access ports 230 are configured to facilitate the entry and exit of a substrate into and out of the loadlock chamber 110.

In one embodiment, the substrate access ports 230 have port liners 235 disposed therein. The port liners 235 are vacuum tight and ensure vacuum integrity between the substrate sub-chambers 220 and either the transfer chamber 120 or the factory interface 105. In one embodiment, the port liners 235 are made from carbon steel, stainless steel, or aluminum sheets or tubing. In one embodiment, the port liners 235 are joined to the chamber liner 215 in a vacuum tight manner, such as welding.

In one embodiment, each of the substrate access ports 230 is selectively sealed by a respective slit valve 226 adapted to selectively isolate the substrate sub-chambers 220 from the environments of the transfer chamber 120 and the factory interface 105. The slit valves 226 are coupled to the chamber body 212 and may be moved between an open and closed position using an actuator (not shown).

In one embodiment, each of the substrate sub-chambers 220 contain a plurality of substrate supports 244, which are configured and spaced such that a substrate placed thereon is elevated with respect to the chamber body 212 or horizontal walls 214. In one embodiment, the substrate supports 244 are pins having a rounded upper end configured to minimize scratching and contamination of substrates placed thereon.

In one embodiment, the loadlock chamber 110 is supported by a base member 260. In one embodiment, the base member 260 is comprised of reinforced concrete. In one embodiment, the base member 260 is constructed integrally with a floor of a fabrication plant containing the processing system 100.

FIG. 2B is a schematic, cross-sectional view of the loadlock chamber 110 taken along section line B-B of FIG. 2A. The sidewalls of each of the substrate sub-chambers 220 include at least one port disposed therethrough to facilitate controlling the pressure within the interior volume of each chamber. In one embodiment, the chamber body 212 includes vent ports 204 formed through a sidewall 206 and vacuum ports 207 formed through a sidewall 208 for venting and pumping down the substrate sub-chambers 220. Valves 250 are coupled to the vent ports 204 and the vacuum ports 207. The vacuum ports 207 are coupled to one or more vacuum pumps 209 to selectively lower the pressure within the interior volume of each of the substrate sub-chambers 220 to a level that substantially matches the pressure of the transfer chamber 120, such as between about 0.1 torr to about 10 torr.

In one embodiment, the vent ports 204 and the vacuum ports 207 have port liners 225 disposed therein. The port liners 225 are vacuum tight and ensure vacuum integrity between the substrate sub-chambers 220 and valves 250. In one embodiment, the port liners 225 are carbon steel, stainless steel, or aluminum sheets or tubing. In one embodiment, the port liners 225 are joined to the chamber liner 215 in a vacuum tight manner, such as welding.

In one embodiment, the chamber liner 215 is spaced apart from the chamber body 212 and horizontal chamber walls 214 via spacer 218. In one embodiment, the spacer 218 is a plurality of metal bars, such as carbon steel, stainless steel, or aluminum bars. In one embodiment, the spacer 218 may be attached to the mesh 211, such as by welding. In one embodiment, the spacer 218 may be attached to the chamber liner 215. In one embodiment, the spacer 218 may be insulative, such as a plurality of refractory bricks or the like.

In one embodiment, vent ports 254 and vacuum ports 257 are disposed through the chamber sidewalls 206 and 208, respectively, and are in fluid communication with the space between the chamber body 212 and the chamber liner 215. Valves 250 may be coupled to the vent ports 254 and the vacuum ports 257. The vacuum ports 257 are coupled to one or more vacuum pumps 209 to selectively lower the pressure within the space between the chamber body 212 and the chamber liner 215 to substantially match that within the sub-chambers 220 in order to minimize stresses on the chamber liner 215.

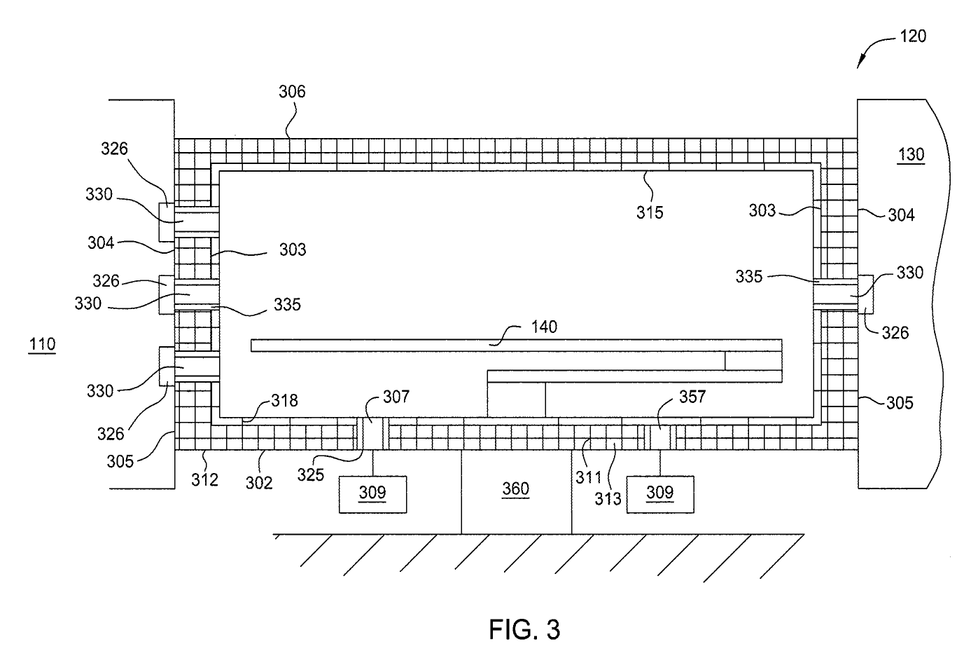

FIG. 3 is a schematic, cross-sectional view of one embodiment of the transfer chamber 120 according to the present invention. The transfer chamber 120 may include at least one transfer robot 140 disposed therein. The transfer chamber 120 may be coupled to one or more loadlock chambers 110. The transfer chamber 120 may also be coupled to at least one process chamber 130.

In one embodiment, the transfer chamber 130 includes a chamber body 312. The chamber body 312 may have a bottom 302, sidewalls 304, and a lid 306. In one embodiment, the sidewalls 304 adjoin the sidewalls of the loadlock chamber 110 or processing chamber 130 positioned adjacent thereto. The interior surface 303 of the sidewalls 304 may have a cylindrical shape, and the exterior surface 305 of the sidewalls 304 may have a hexagonal shape as shown in FIG. 1 or other shape, such as an octagonal shape to match the desired number of chamber positions.

In one embodiment, the chamber body 312 is constructed of reinforced concrete. In one embodiment, the chamber body 312 includes a reinforcing mesh 311 of wires or bars distributed with concrete filler 313 cured thereabout. The mesh 311 may be pre-tensioned to ensure the concrete filler 313 in the chamber body 312 remains in compression after curing. The mesh 311 may be sized and distributed to withstand the pressures encountered in normal operation of the transfer chamber 120. In one embodiment, the interior surface of the chamber body 312 may be ground, polished, or otherwise treated, such as by applying permeating resins, to produce a vacuum tight finish.

In one embodiment, the reinforcing mesh 311 is comprised of a network of welded, carbon or stainless steel wires and/or bars. In one embodiment, a chamber liner 315 is disposed within and lining the chamber body 312. In one embodiment the chamber liner 315 is a thin-walled structure formed in a vacuum tight manner. In one embodiment, the chamber liner 315 is constructed by welding sheets of carbon steel, stainless steel, or aluminum. In one embodiment, the chamber liner 315 is constructed by hydroforming aluminum tubing.

In one embodiment, the concrete filler 313 is a cement, sand, and water mixture plastered within and about the reinforcing mesh 311. In one embodiment, the chamber liner 315 is attached to the reinforcing mesh 311, and the concrete filler 313 is applied between the chamber liner 315 and the reinforcing mesh 311 as well as within and about the reinforcing mesh 311.

Each sidewall 304 may include one or more substrate ports 330 through which a substrate may be transferred into or out of the transfer chamber 120. A slit valve 326 may selectively open and close the ports 330 via an actuator (not shown). The chamber body 312 may include a vacuum port 307 coupled to a vacuum pump 309 to pump down the pressure level inside the transfer chamber 120.

In one embodiment, the substrate access ports 330 have port liners 335 disposed therein. The port liners 335 are vacuum tight and ensure vacuum integrity between the transfer chamber 120 and either the loadlock chamber 110 or the process chambers 130. In one embodiment, the port liners 335 are carbon steel, stainless steel, or aluminum sheets or tubing. In one embodiment, the port liners 335 are joined to the chamber liner 315 in a vacuum tight manner, such as welding.

In one embodiment, the vacuum port 307 has a port liner 325 disposed therein. The port liner 325 is vacuum tight to ensure vacuum integrity between the transfer chamber 120 and the vacuum pump 309. In one embodiment, the port liner 325 is carbon steel, stainless steel, or aluminum sheets or tubing. In one embodiment, the port liner 325 is joined to the chamber liner 315 in a vacuum tight manner, such as welding.

In one embodiment, the chamber liner 315 is spaced apart from the chamber body 312 via a spacer 318. In one embodiment, the spacer 318 is a plurality of metal bars, such as carbon steel, stainless steel, or aluminum bars. In one embodiment, the spacer 318 may be attached to the mesh 313, such as by welding. In one embodiment, the spacer 318 may be attached to the chamber liner 315. In one embodiment, the spacer 318 may be insulative, such as a plurality of refractory brick or the like.

In one embodiment, at least one vacuum port 357 is disposed through the transfer chamber body 312 and is in fluid communication with the space between the chamber body 312 and the chamber liner 315. The vacuum port 357 is coupled to one or more vacuum pumps 309 to selectively lower the pressure within the space between the chamber body 312 and the chamber liner 315 to substantially match that within the transfer chamber 120, such as between about 0.1 torr to about 10 torr, in order to minimize stresses on the chamber liner 315.

In one embodiment, the transfer chamber 120 is supported by a base member 360. In one embodiment, the base member 360 is comprised of reinforced concrete. In one embodiment the base member 360 is constructed integrally with a floor of a fabrication plant containing the processing system 100.

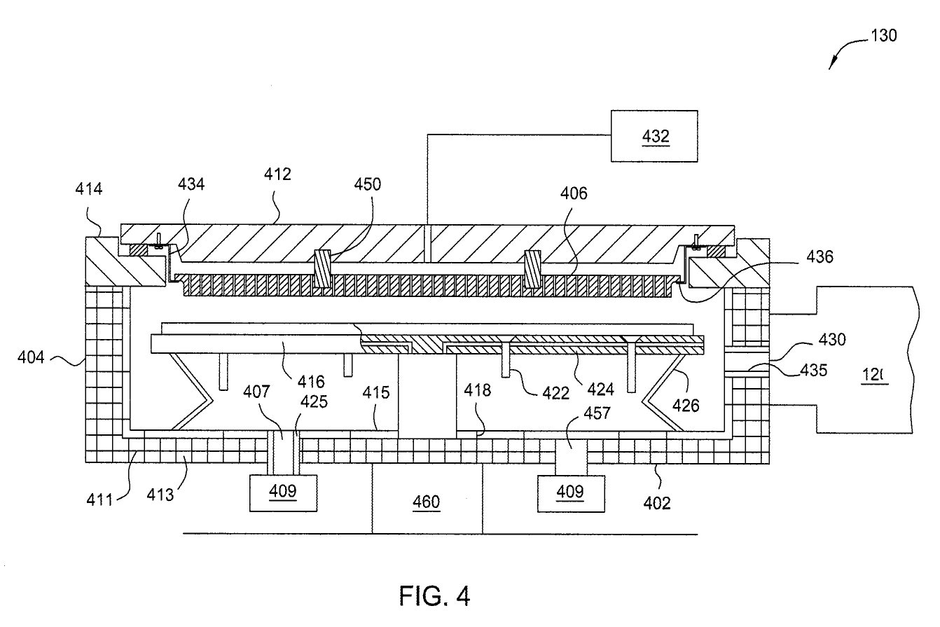

FIG. 4 is a schematic, cross-sectional view of one embodiment of a process chamber 130. The chamber 130 generally includes a bottom 402, sidewalls 404, a showerhead 406, and a susceptor 416, which cumulatively define a process volume. In one embodiment, one of the walls 404 adjoins the sidewall of the transfer chamber 120 positioned adjacent thereto.

In one embodiment, the bottom 402 and walls 404 are constructed of reinforced concrete. In one embodiment, the bottom 402 and walls 404 include a reinforcing mesh 411 of wires or bars distributed with concrete filler 413 cured thereabout. The mesh 411 may be pre-tensioned to ensure the concrete filler 413 in the chamber bottom 402 and walls 404 remains in compression after curing. The mesh 411 may be sized and distributed to withstand the pressures encountered in normal operation of the process chamber 130. In one embodiment, the interior surface of the chamber bottom 402 and walls 404 may be ground, polished, or otherwise treated, such as by applying permeating resins, to produce a vacuum tight finish.

In one embodiment, the reinforcing mesh 411 is comprised of a network of welded, carbon or stainless steel wires and/or bars. In one embodiment, a chamber liner 415 is disposed within and lining the process chamber 130. In one embodiment, the chamber liner 415 is a thin-walled structure formed in a vacuum tight manner. In one embodiment, the chamber liner 415 is constructed by bending and/or welding sheets of carbon steel, stainless steel, or aluminum. In one embodiment, the chamber liner 415 is constructed by hydroforming aluminum tubing.

In one embodiment, the concrete filler 413 is a cement, sand, and water mixture plastered within and about the reinforcing mesh 411. In one embodiment, the chamber liner 415 is attached to the reinforcing mesh 411, and the concrete filler 413 is applied between the chamber liner 415 and the reinforcing mesh 411 as well as within and about the reinforcing mesh 411.

The process volume of the process chamber 130 may be accessed through a substrate port 430 in communication with substrate port 330, such that a substrate may be transferred between the process chamber 130 and the transfer chamber 120. In one embodiment, the substrate access port 430 has a port liner 435 disposed therein. The port liner 435 is vacuum tight and ensures vacuum integrity between the process chamber 130 and the transfer chamber 120. In one embodiment, the port liner 435 is carbon steel, stainless steel, or aluminum sheets or tubing. In one embodiment, the port liner 435 is joined to the chamber liner 415 in a vacuum tight manner, such as welding.

The susceptor 416 may be coupled to an actuator (not shown) to raise and lower the susceptor 416. Lift pins 422 may be moveably disposed through the susceptor 416 to support a substrate prior to placement onto the susceptor 416 and after removal from the susceptor 416. The susceptor 416 may include heating and/or cooling elements 424 to maintain the susceptor 416 at a desired temperature. The susceptor 416 may also include grounding straps 426 to provide RF grounding at the periphery of the susceptor 416.

In one embodiment, the showerhead 406 is mechanically coupled to a backing plate 412 by a suspension 434. The suspension 434 may have a ledge 436 upon which the showerhead 406 may rest. The backing plate 412 may rest on a ledge 414 coupled with the chamber walls 404 to seal the chamber 130. The showerhead may also be mechanically coupled to the backing plate 412 by one or more coupling supports 450 to help prevent sag and/or control the straightness/curvature of the showerhead 406. In one embodiment, twelve coupling supports 450 may be used to mechanically couple the showerhead 406 to the backing plate 412.

In one embodiment, a gas source 432 is coupled to the backing plate 412 to provide gas through gas passages in the showerhead 406. In one embodiment, the gas source 432 may comprise a processing gas source. In another embodiment, the gas source 432 may further comprise a cleaning gas source such as a remote plasma source, for cleaning chamber components between processing substrates.

In one embodiment, a vacuum port 407 is disposed through the bottom 402 of the chamber 130 and in fluid communication with the process volume and a vacuum pump 409 to pump down the pressure level of the chamber 130. In one embodiment, the vacuum port 407 has a port liner 425 disposed therein. The port liner 425 is vacuum tight to ensure vacuum integrity between the process chamber 130 and the vacuum pump 409. In one embodiment, the port liner 425 is carbon steel, stainless steel, or aluminum sheets or tubing. In one embodiment, the port liner 425 is joined to the chamber liner 415 in a vacuum tight manner, such as welding.

In one embodiment, the chamber liner 415 is spaced apart from the chamber bottom 402 and walls 404 via a spacer 418. In one embodiment, the spacer 418 is a plurality of metal bars, such as carbon steel, stainless steel, or aluminum bars. In one embodiment, the spacer 418 may be attached to the mesh 411, such as by welding. In one embodiment, the spacer 418 may be attached to the chamber liner 415. In one embodiment, the spacer 418 may be insulative, such as a plurality of refractory brick or the like.

In one embodiment, at least one vacuum port 457 is disposed through the chamber bottom 402 as shown in FIG. 4. In one embodiment, the vacuum port 457 is disposed through the chamber wall 404 (not shown). The vacuum port 457 may be in fluid communication with the space between the chamber bottom 402 and the chamber liner 415. The vacuum port 457 may also be in fluid communication with the space between the chamber wall 404 and the chamber liner 415. The vacuum port 457 is coupled to one or more vacuum pumps 409 to selectively lower the pressure within the space between the chamber bottom 402 and walls 404 and the chamber liner 415 to substantially match that within the process chamber 130, such as between about 0.1 torr to about 10 torr, in order to minimize stresses on the liner 415.

In one embodiment, the process chamber 130 is supported by a base member 460. In one embodiment, the base member 460 is comprised of reinforced concrete. In one embodiment the base member 460 is constructed integrally with a floor of a fabrication plant containing the processing system 100.

Embodiments of the present invention provide a substrate processing system with both the individual vacuum chambers and the structural support therefore constructed of reinforced concrete. Not only are such structures less costly to manufacture, but they also require less energy to produce. Furthermore, the concrete reinforced processing system may be constructed at its final destination, minimizing the energy consumption and costs of delivery as well.

While the foregoing is directed to embodiments of the present invention, other and further embodiments of the invention may be devised without departing from the basic scope thereof, and the scope thereof is determined by the claims that follow.

1. A substrate processing system, comprising:
a loadlock chamber having a chamber body and a substrate transfer port disposed therethrough, wherein the loadlock chamber body is comprised of reinforced concrete;
a transfer chamber having a first wall with a substrate transfer port disposed therethrough and a second wall with a substrate transfer port disposed therethrough, wherein the substrate transfer port in the first wall is in fluid communication with the substrate transfer port in the loadlock chamber body, and wherein the first and second transfer chamber walls are comprised of reinforced concrete; and
a vacuum processing chamber having a bottom, a sidewall, a showerhead, and a substrate support member forming a substrate processing region, wherein the sidewall has a substrate transfer port in fluid communication with the substrate transfer port of the second wall of the substrate transfer chamber, and wherein the bottom, and sidewall are comprised of reinforced concrete.

2. The substrate processing system of claim 1, wherein the transfer chamber has a base member comprising reinforced concrete.

3. The substrate processing system of claim 1, wherein the vacuum processing chamber further comprises a liner positioned adjacent the bottom and sidewall.

4. The substrate processing system of claim 3, wherein an open region is defined between the liner and the bottom and sidewall via a spacer member.

5. The substrate processing system of claim 4, wherein the vacuum processing chamber further comprises a vacuum pump in fluid communication with the open region.

6. The substrate processing system of claim 3, wherein the sidewall has a port liner disposed within the substrate transfer port.

7. A vacuum processing chamber, comprising:
a bottom wall, a sidewall, a showerhead, and a susceptor defining a processing volume;
a reinforcing member disposed within the bottom wall; and
aggregate filler disposed within the bottom wall.

8. The vacuum processing chamber of claim 7, further comprising a chamber liner disposed adjacent the bottom wall.

9. The vacuum processing chamber of claim 8, wherein a space is defined between the chamber liner and the bottom wall via a spacer member.

10. The vacuum processing chamber of claim 9, further comprising a vacuum pump in fluid communication with the space defined between the chamber liner and the bottom wall.

11. The vacuum processing chamber of claim 8, wherein a transfer port is defined through the sidewall and has a port liner disposed therein.

12. The vacuum processing chamber of claim 7, wherein the reinforcing member is pretensioned wire mesh.

13. The vacuum processing chamber of claim 12, wherein the aggregate filler is a cured mixture comprising cement, sand, and water.

14. The vacuum processing chamber of claim 7, further comprising a base member supporting the bottom wall and comprising reinforced concrete.

15. A vacuum chamber, comprising:
a chamber body having walls defining a processing region therein, the chamber body having a substrate transfer port and a first vacuum port disposed therethrough;
a vacuum pump in fluid connection with the processing region via the first vacuum port;
a structural mesh disposed within the walls of the chamber body; and
a filler material disposed within the walls of the chamber body.

16. The vacuum chamber of claim 15, further comprising a chamber liner juxtaposed the walls within the chamber body.

17. The vacuum chamber of claim 16, wherein a volume is defined between the chamber liner and the chamber body.

18. The vacuum chamber of claim 17, further comprising a second vacuum port disposed through the chamber body and in fluid communication with the volume between the chamber liner and the chamber body.

19. The vacuum chamber of claim 15, wherein the filler material is concrete.

20. The vacuum chamber of claim 19, wherein the structural mesh is a pretensioned mesh of reinforcing bars.

21. A method of constructing a vacuum processing chamber, comprising:
forming a structural mesh in the shape of a chamber body having a bottom wall and a side wall;
attaching a chamber liner having a bottom wall and a side wall to the structural mesh;
distributing a filler material within and about the structural mesh; and
curing the filler material.

22. The method of claim 21, wherein the structural mesh is a mesh of reinforcing bars.

23. The method of claim 21, further comprising applying a tensile load to the structural mesh.

24. The method of claim 21, wherein the filler material is a concrete mixture.

25. The method of claim 21, further comprising attaching a port liner to the chamber liner.
